(19) United States
(12) Patent Application Publication
(10) Pub. No.: US 2015/0377928 A1
(43) Pub. Date: Dec. 31, 2015

(54) VOLTAGE MEASURING DEVICE

(71) Applicant: TOSHIBA MITSUBISHI-ELECTRIC INDUSTRIAL SYSTEMS CORPORATION, Tokyo (JP)

(72) Inventors: Takeo SUZUKI, Tokyo (JP); Shigehikp MATSUDA, Tokyo (JP)

(73) Assignee: TOSHIBA MITSUBISHI-ELECTRIC INDUSTRIAL SYSTEMS CORPORATION, Tokyo (JP)

(21) Appl. No.: 14/768,064

(22) PCT Filed: Mar. 29, 2013
(86) PCT No.: PCT/JP2013/059559

§ 371 Date: Aug. 14, 2015

(51) Int. Cl. G01R 15/06; G01R 19/00

(52) U.S. Cl. CPC G01R 15/06; G01R 19/0084

(57) ABSTRACT

A voltage measuring device that can contactlessly measure a direct-current voltage of a measurement target is provided. For that purpose, the voltage measuring device includes: a dielectric body provided so as to be able to face a conductor of a measurement target; an electrode provided on the dielectric body; a capacitor that, upon being connected to the electrode, holds a potential having a one-to-one correlation with a potential of the electrode; and a switch provided so as to be able to connect the electrode and the capacitor, and upon the electrode and the capacitor being disconnected, enable a voltage between opposite ends of the capacitor to be output.

### TECHNICAL FIELD

The present invention relates to a voltage measuring device.

### BACKGROUND ART

Voltage measuring devices including a detection electrode, first to fourth variable capacitive elements, and a voltage generating circuit have been proposed. In such voltage measuring devices, the detection electrode is capacitively-coupled to a measurement target. Capacitances of the respective variable capacitive elements vary so that the product of respective impedances of the first variable capacitive element and the third variable capacitive element and the product of respective impedances of the second variable capacitive element and the fourth variable capacitive element are equal to each other. The voltage generating circuit generates a voltage so that a current that flows from the detection electrode to a ground point via a point of junction between the second variable capacitive element and the fourth variable capacitive element becomes zero. The voltage is determined as a voltage of the measurement target. Such voltage measuring devices can contactlessly measure a voltage of a measurement target (for example, see Patent Literature 1).

### CITATION LIST

### Patent Literature

Patent Literature 1: Japanese Patent No. 4607752

### SUMMARY OF INVENTION

### Technical Problem

However, in such voltage measuring devices, until the current finally becomes zero, an input impedance of a circuit connected to the detection electrode is finite. Thus, it is impossible to measure a direct-current voltage.

The present invention has been made to solve the aforementioned problem, and an object of the present invention is to provide a voltage measuring device that can contactlessly measure a direct-current voltage of a measurement target.

### Means for Solving the Problems

A voltage measuring device of the present invention includes a dielectric body provided so as to be able to face a conductor of a measurement target; an electrode provided on the dielectric body; a capacitor that, upon being connected to the electrode, holds a potential having a one-to-one correlation with a potential of the electrode; and a switch provided so as to be able to connect the electrode and the capacitor, and upon the electrode and the capacitor being disconnected, enable a voltage between opposite ends of the capacitor to be output.

### Advantageous Effect of Invention

The present invention enables contactless measurement of a direct-current voltage of a measurement target.

### BRIEF DESCRIPTION OF THE DRAWINGS

FIG. 1 is a circuit diagram of a voltage measuring device according to Embodiment 1 of the present invention.

FIG. 2 is a diagram of a voltage measuring circuit in the voltage measuring device according to Embodiment 1 of the present invention.

FIG. 3 is a diagram of an equivalent circuit including the voltage measuring device according to Embodiment 1 of the present invention.

FIG. 4 is a circuit diagram of a voltage measuring device according to Embodiment 2 of the present invention.

FIG. 5 is a circuit diagram of a voltage measuring device according to Embodiment 4 of the present invention.

FIG. 6 is a circuit diagram of a voltage measuring device according to Embodiment 5 of the present invention.

FIG. 7 is a circuit diagram of a voltage measuring device according to Embodiment 7 of the present invention.

### DESCRIPTION OF EMBODIMENTS

Embodiments of the present invention will be described with reference to the accompanying drawings. In the drawings, parts that are identical or correspond to each other are provided with a same reference numeral, and overlapping description thereof will arbitrarily be simplified or omitted.

### Embodiment 1

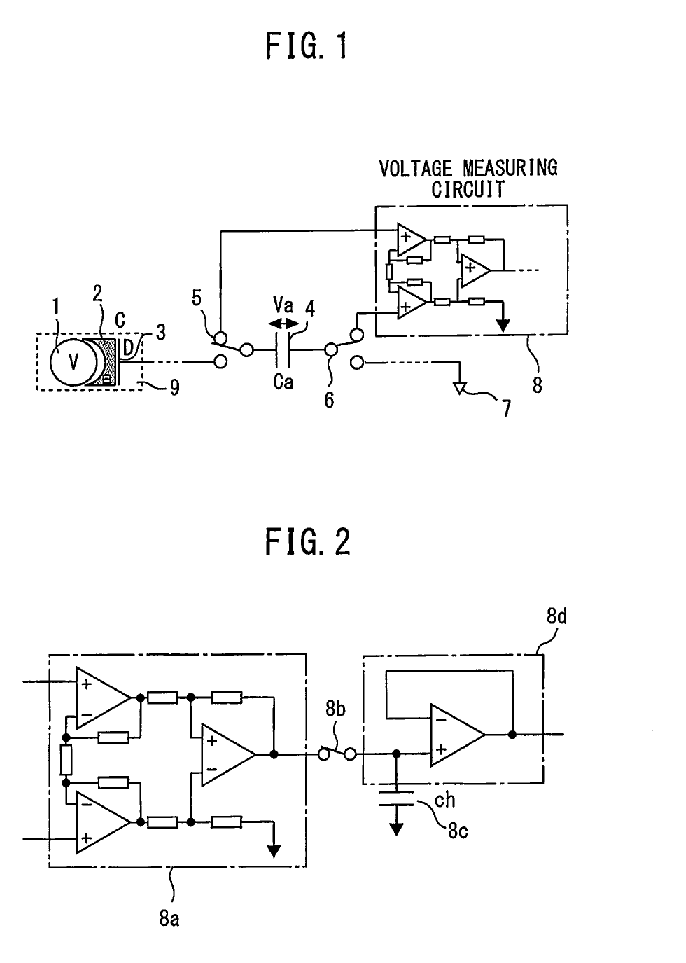

FIG. 1 is a circuit diagram of a voltage measuring device according to Embodiment 1 of the present invention.

In FIG. 1, a conductor 1 of a measurement target is a wiring of, e.g., an electronic controller that controls an electronic device. For example, the conductor 1 is a control power supply wire, a control signal wire or an earth wire of an electronic controller.

As illustrated in FIG. 1, the voltage measuring device includes a dielectric body 2, an electrode 3, a capacitor 4, a switch 5, a switch 6, a signal common 7, and a voltage measuring circuit 8.

The dielectric body 2 is provided so as to face the conductor 1. The electrode 3 is connected to the dielectric body 2. The electrode 3 is not in contact with the conductor 1 because the dielectric body 2 is interposed therebetween. The capacitor 4 has an electrostatic capacitance Ca. One front end side of the switch 5 is connected to the electrode 3. A rear end side of the switch 5 is connected to a front end side of the capacitor 4. A front end side of the switch 6 is connected to a rear end side of the capacitor 4. The signal common 7 is connected to one rear end side of the switch 6. The voltage measuring circuit 8 includes, e.g., a differential amplifier. One front end side of the voltage measuring circuit 8 is connected to the other front end side of the switch 5. The other front end side of the voltage measuring circuit 8 is connected to the other rear end side of the switch 6.

When the conductor 1 has a potential V, the conductor 1, the dielectric body 2 and the electrode 3 function as a capacitor 9. The capacitor 9 has an electrostatic capacitance C. In the voltage measuring device, a front end of the switch 5 is shifted to the electrode 3 side. Simultaneously with this, a rear end of the switch 6 is shifted to the signal common 7 side. Here, the potential V of the conductor 1 is divided by a circuit formed between the capacitor 9 and the signal common 7.

For example, as illustrated in FIG. 1, where the circuit is formed by the serially-connected capacitors 4 and 9 alone, the potentials of the capacitors 4 and 9 are divided at a ratio of the electrostatic capacitance C:the electrostatic capacitance Ca. In other words, the potentials of the capacitors 4 and 9 have a one-to-one correlation with the potential V of the conductor 1.

When the capacitor 4 has a divisional voltage as a potential Va, the front end of the switch 5 is shifted to the voltage measuring circuit 8 side. Simultaneously with this, the rear end of the switch 6 is shifted to the voltage measuring circuit 8 side. Then, the capacitor 4 releases charge toward the voltage measuring circuit 8. The voltage measuring circuit 8 measures the potential Va based on the charge. The voltage measuring circuit 8 calculates the potential V of the conductor 1 based on the potential Va.

Here, variation of the potential Va is determined according to an input impedance in a time constant Ca* of the voltage measuring circuit 8. For example, as illustrated in FIG. 1, where a differential amplifier is used in the voltage measuring circuit 8, the input impedance is high. In this case, the variation of the potential Va is small.

Next, an example of the voltage measuring circuit 8 will be described with reference to FIG. 2.

FIG. 2 is a diagram of a voltage measuring circuit in the voltage measuring device according to Embodiment 1 of the present invention.

As illustrated in FIG. 2, the voltage measuring circuit 8 includes a differential amplifier 8a, a switch 8b, a hold capacitor 8c and a buffer amplifier 8d.

One front end side of the differential amplifier 8a is connected to the other front end side of the switch 5. The other front end side of the differential amplifier 8a is connected to the other rear end side of the switch 6. A front end side of the switch 8b is connected to a rear end side of the differential amplifier 8a. A front end side of the hold capacitor 8c is connected to a rear end side of the switch 8b. A rear end side of the hold capacitor 8c is connected to a common of the voltage measuring circuit 8. A front end side of the buffer amplifier 8d is connected to the rear end side of the switch 8b.

In the voltage measuring circuit 8, the front end of the switch 5 and the rear end of the switch 6 are simultaneously shifted to the voltage measuring circuit 8 side, and then the switch 8b is closed. Here, the buffer amplifier 8d outputs a potential Va of the rear end of the differential amplifier 8a. Here, the hold capacitor 8c holds the potential Va of the rear end of the differential amplifier 8a. Subsequently, the switch 8b is opened. Here, the buffer amplifier 8d outputs the potential Va held by the hold capacitor 8c. In other words, the output of the buffer amplifier 8d cannot be inconstant. During that time, the front end of the switch 5 is connected to the electrode 3 side. Simultaneously with this, the rear end of the switch 6 is shifted to the signal common 7 side.

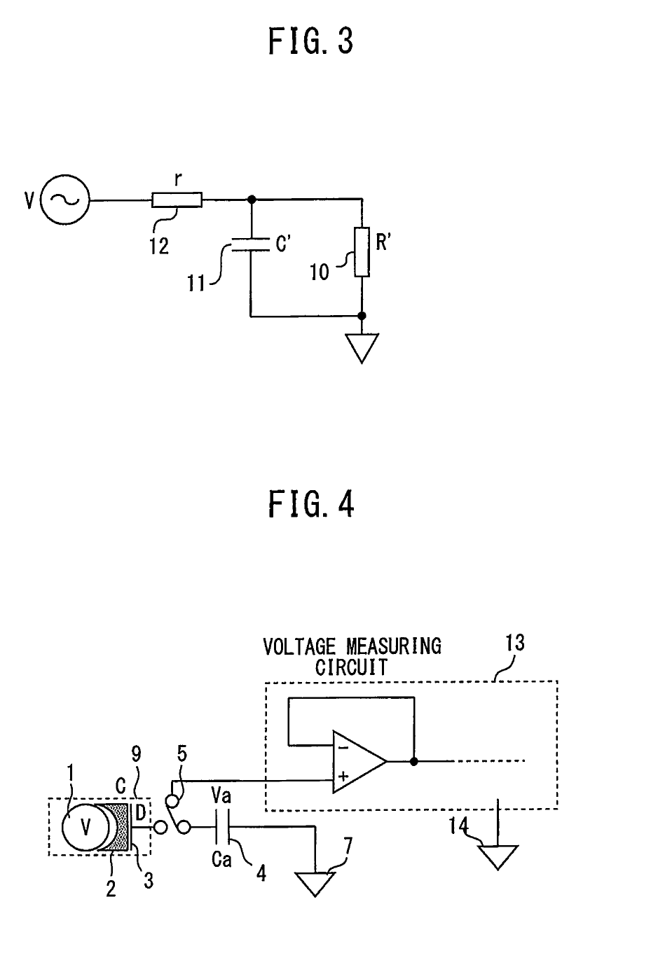

Next, an equivalent circuit of the electrostatic capacitance Ca and an entire measurement target will be described with reference to FIG. 3.

FIG. 3 is a diagram of an equivalent circuit including the voltage measuring device according to Embodiment 1 of the present invention.

In FIG. 3, R′ is an impedance of a circuit of a measurement target 10. C is an electrostatic capacitance of a capacitor 11 resulting from combination of the capacitor 4 and the capacitor 9, and r is an impedance of a line resistance 12. V is an output potential of a voltage generation source such as a DC power supply including a voltage regulator or a logic element that outputs a digital signal.

From the perspective of the alternate-current output potential V, an impedance Z corresponds to r+R′/(1+jωR′C′). In other words, the output potential V is affected by a load on the circuit of the measurement target 10, and the capacitor 11.

In the voltage measuring device, the front end of the switch 5 is shifted to the electrode 3 side. Simultaneously with this, the rear end of the switch 6 is connected to the signal common 7 side. This state lasts for time t1. During that time, the capacitors 4 and 9 accumulate charge. Subsequently, the front end of the switch 5 is shifted to the voltage measuring circuit 8 side. Simultaneously with this, the rear end of the switch 6 is shifted to the voltage measuring circuit 8 side. This state lasts for time t2. During that time, the voltage measuring circuit 8 measures an output potential Va.

An interval between the charge accumulation and the measurement of the output potential Va is set to time t3. In other words, during the time t3, the front end of the switch 5 and the rear end of the switch 6 are continuously opened for the time t3.

In the voltage measuring device, the time t1 and the time t2 are set to be sufficiently shorter than the time t3. Thus, the output potential Va can microscopically be treated as a direct current. In other words, variation of the output potential Va is small.

For example, where a measurement target signal is a high-frequency noise signal of several tens of MHz, the time t3 may be ten-odd nanoseconds or more, and the time t1 and the time t2 may be several nanoseconds or less. In this case, as long as the electrostatic capacitance C′ is around several picofarads, the voltage measuring device has a sufficient measurement capability.

According to Embodiment 1 described above, the capacitor 4 holds a potential Va that is in a one-to-one correlation with a potential V of the conductor 1. The potential Va of the capacitor 4 is measured after disconnection between the capacitor 4 and the capacitor 9. Here, it is not necessary to take an impedance of the measurement target circuit into account. Thus, contactless voltage measurement that is free from frequency dependence can be performed. In other words, contactless direct-current voltage measurement can be performed for the conductor 1.

Here, a measured potential does not have a continuous value. Here, a resolution of the measured potential is determined by operation speeds of the switches 5, 6 and 8b. If a response speed of several tens of MHz, which is required for noise measurement, is provided, a sufficient response capability can be ensured even if an alternate-current voltage is measured.

Also, where a low voltage of around several volts is measured, the conductor 1 and the electrode 3 may be shielded. In other words, a sufficient area of the conductor 1 may be surrounded by, e.g., another conductor. In this case, an effect of an ambient electric field is suppressed. As a result, an electric field generated from the potential V of the conductor 1 can accurately be received by the electrode 3.

Also, when the switches 5 and 6 are shifted to the voltage measuring circuit 8 side, a value of the potential Va held by the capacitor 4 may be read directly by an AD converter (not illustrated). In this case, no AD conversion may be performed when the switch 6 is shifted to the signal common 7 side simultaneously with the shift of the switch 5 to the electrode 3 side. In this case, also, the output of the buffer amplifier 8d cannot be inconstant.

### Embodiment 2

FIG. 4 is a circuit diagram of a voltage measuring device according to Embodiment 2 of the present invention. Here, parts that are identical to or correspond to those of Embodiment 1 are provided with reference numerals that are the same as those of Embodiment 1, and description thereof will be omitted.

In Embodiment 2, a simplest voltage measuring circuit 13 is used. In the voltage measuring circuit 13, a switch 6 is not used. In other words, a rear end of a capacitor 4 is directly connected to a signal common 7. A common 14 of the voltage measuring circuit 13 is identical to the signal common 7. A potential of the common 14 can be obtained by bringing the voltage measuring device into contact with the conductor.

In the voltage measuring device, a switch 5 is shifted to the electrode 3 side. In this case, a serial circuit of a capacitor 4 and a capacitor 9 is formed. Here, a potential Va of the capacitor 4 is VC/(C+Ca). Subsequently, the switch 5 is shifted to the voltage measuring circuit 13 side. In this case, the voltage measuring circuit 13 measures the potential Va of the capacitor 4.

Where there is no change in measurement conditions such as a shape of the conductor 1, a coat of the conductor 1 and/or attachment of a dielectric body 2, an electrostatic capacitance C has a fixed value. In this case, the voltage measuring circuit 13 uniquely calculates Va(1+Ca/C) as a potential V of the conductor 1.

According to Embodiment 2 described above, a switch 6 is not used. In other words, where there is no change in measurement conditions, a potential V of the conductor 1 can uniquely be derived by the simple voltage measuring circuit 13.

### Embodiment 3

A voltage measuring device according to Embodiment 3 is substantially equivalent to the voltage measuring device according to Embodiment 2. Here, parts that are identical to or correspond to those of Embodiment 2 are provided with reference numerals that are the same as those of Embodiment 2, and description thereof will be omitted.

In Embodiment 3, a dielectric body 2 and an electrode 3 are formed so as to be sufficiently large. As a result, an electrostatic capacitance C becomes sufficiently larger than an electrostatic capacitance Ca. In this case, Va(1+Ca/C) is substantially equal to Va. In other words, a potential V of a conductor 1 is substantially equal to a potential Va of a capacitor 4.

According to Embodiment 3 described above, the electrostatic capacitance C is sufficiently larger than the electrostatic capacitance Ca. Thus, as opposed to Embodiment 2, even if there is change in measurement conditions, an error in measurement of the potential V of the conductor 1 can be made smaller than a preset value.

Also, as described in Embodiment 1, the electrostatic capacitance C and the electrostatic capacitance Ca affect a voltage of a measurement target itself due to a load on the measurement target. Thus, for example, when a DC power supply voltage of an electronic device is observed, an electrostatic capacitance C may be made large as long as the electrostatic capacitance C and an electrostatic capacitance Ca can be regarded as being sufficiently small compared to a smoothing capacitor on the output side of the DC power supply.

### Embodiment 4

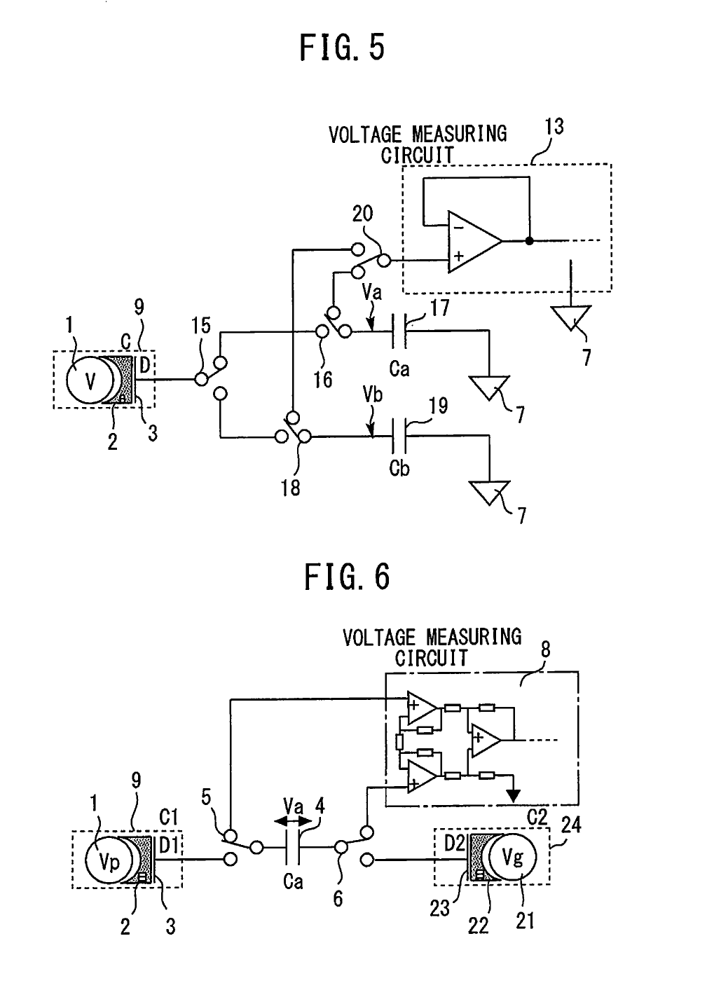

FIG. 5 is a circuit diagram of a voltage measuring device according to Embodiment 4 of the present invention. Here, parts that are identical to or correspond to those of Embodiment 2 are provided with reference numerals that are the same as those of Embodiment 2, and description thereof will be omitted.

In Embodiment 4, a circuit between an electrode 3 and a voltage measuring circuit 13 is different from the circuit in Embodiment 2. More specifically, between the electrode 3 and the voltage measuring circuit 13, a switch 15, a switch 16, a capacitor 17, a switch 18, a capacitor 19 and a switch 20 are provided.

A front end side of the switch 15 is connected to a rear end side of the electrode 3. One front end side of the switch 16 is connected to one rear end side of the switch 15. The capacitor 17 has an electrostatic capacitance Ca. A front end side of the capacitor 17 is connected to a rear end side of the switch 16. A rear end side of the capacitor 17 is connected to a signal common 7. One front end side of the switch 18 is connected to the other rear end side of the switch 15. The capacitor 19 has an electrostatic capacitance Cb. A front end side of the capacitor 19 is connected to a rear end side of the switch 18. A rear end side of the capacitor 19 is connected to the signal common 7. One front end side of the switch 20 is connected to the other front end side of the switch 16. The other front end side of the switch 20 is connected to the other front end side of the switch 18. A rear end side of the switch 20 is connected to a front end side of the voltage measuring circuit 13.

In the voltage measuring device, if the switch 15 is shifted to the capacitor 17 side, a potential Va of the capacitor 17 is VC/(C+Ca). On the other hand, if the switch 15 is shifted to the capacitor 19 side, a potential Vb of the capacitor 19 is VC/(C+Cb).

The voltage measuring circuit 13 eliminates an electrostatic capacitance C from the potential Va of the capacitor 17 and the potential Vb of the capacitor 19. In other words, the voltage measuring circuit 13 calculates Va(1+Ca(Vb−Va)/(Va·Ca−Vb·Cb) as a potential V of a conductor 1.

According to Embodiment 4 described above, the potential V of the conductor 1 is calculated without including the electrostatic capacitance C. Thus, even if the electrostatic capacitance C of a capacitor 9 varies or is unstable, the potential V of the conductor 1 can correctly be calculated. In other words, as opposed to Embodiment 2, even where there is change in measurement conditions, the potential V of the conductor 1 can correctly be measured.

### Embodiment 5

FIG. 6 is a circuit diagram of a voltage measuring device according to Embodiment 5 of the present invention. Here, parts that are identical to or correspond to those of Embodiment 1 are provided with reference numerals that are the same as those of Embodiment 1, and description thereof will be omitted.

The voltage measuring device according to Embodiment 5 can contactlessly measure a potential of a conductor 21 of a signal common as well. More specifically, the voltage measuring device according to Embodiment 5 is the voltage measuring device according to Embodiment 1 with a dielectric body 22 and an electrode 23 added thereto. The dielectric body 22 is provided so as to face the conductor 21. The electrode 23 is connected to the dielectric body 22. The electrode 23 is not in contact with the conductor 21 because the dielectric body 22 is interposed therebetween. A front end side of the electrode 23 is connected to the other rear end side of a switch 6.

In Embodiment 5, a conductor 1, a dielectric body 2 and an electrode 3 function as a capacitor 9. The capacitor 9 has an electrostatic capacitance C1. On the other hand, the conductor 21, the dielectric body 22 and the electrode 23 function as a capacitor 24. The capacitor 24 has an electrostatic capacitance C2.

In FIG. 6, Vp is a potential of the conductor 1. Vg is a potential of the conductor 21. In this state, the switch 5 is shifted to the electrode 3 side. Simultaneously with this, the switch 6 is shifted to the electrode 23 side. In this case, an impedance between the potential Vp and the potential Vg corresponds to 1/(ωC1)+1/(ωCa)+1/(ωC2).

In this case, a current flowing in a capacitor 4 corresponds to (Vp−Vg)/(1/(ωC1)+1/(ωCa)+1/(ωC2)).

In this case, a voltage Va between opposite ends of the capacitor 4 corresponds to ((Vp−Vg)/(1/(ωC1)+1/(ωCa)+1/(ωC2)))·(1/jωCa). The voltage Va is simplified to (Vp−Vg)·(1/jωCa)/(1/jωC1+1/jωCa+1/jωC2). The voltage Va is simplified to (Vp−Vg)/(Ca/C1+1+Ca/C2). In other words, the voltage Va is not dependent on frequency.

Subsequently, the switch 5 is shifted to the voltage measuring circuit 8 side. Simultaneously with this, switch 6 is shifted to the voltage measuring circuit 8 side. Here, the voltage measuring circuit 8 measures the voltage Va between the opposite ends of the capacitor 4. The voltage measuring circuit 8 calculates Va(Ca/C1+1+Ca/C2) as a potential difference (Vp−Vg) in a measurement target.

According to Embodiment 5 described above, the dielectric body 22 and the electrode 23 are provided also on the signal common side. Thus, the potential Vg of the conductor 21 on the signal common side can also be measured contactlessly.

### Embodiment 6

A voltage measuring device according to Embodiment 6 is substantially equivalent to the voltage measuring device according to Embodiment 5. Here, parts that are identical to or correspond to those of Embodiment 5 are provided with reference numerals that are the same as those of Embodiment 5, and description thereof will be omitted.

In Embodiment 6, a dielectric body 2 and an electrode 3 are formed so as to be sufficiently large. A dielectric body 22 and an electrode 23 are formed so as to be sufficiently large. As a result, an electrostatic capacitance C1 and an electrostatic capacitance C2 are sufficiently larger than an electrostatic capacitance Ca. Thus, a potential difference (Vp−Vg) in a measurement target is substantially equal to a potential Va of a capacitor 4.

According to Embodiment 6 described above, the electrostatic capacitance C1 and the electrostatic capacitance C2 are sufficiently larger than the electrostatic capacitance Ca. Thus, as in Embodiment 3, even if there is change in measurement conditions, an error in measurement of the potential difference (Vp−Vg) in a measurement target can be made smaller than a preset value.

Also, as described in Embodiment 1, the electrostatic capacitance C1, the electrostatic capacitance C2 and the electrostatic capacitance Ca affect a voltage of the measurement target itself due to a load on the measurement target. Thus, for example, in cases where a DC power supply voltage of an electronic device is observed, the electrostatic capacitance C1 and the electrostatic capacitance C2 may be made large as long as the electrostatic capacitance C and the electrostatic capacitance Ca can be regarded as being sufficiently small compared to a smoothing capacitor on the output side of the DC power supply.

### Embodiment 7

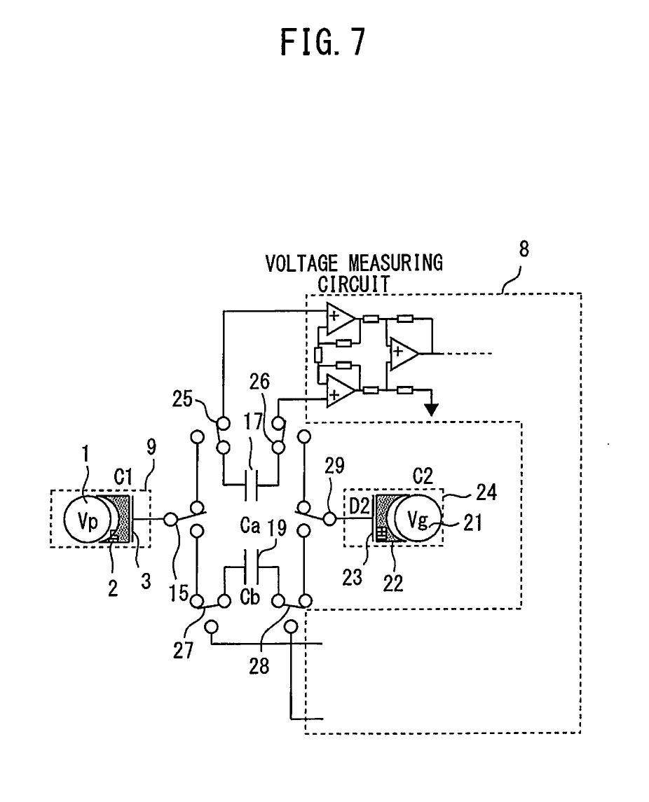

FIG. 7 is a circuit diagram of a voltage measuring device according to Embodiment 7 of the present invention. Here, parts that are identical to or correspond to those of Embodiments 4 and 5 are provided with reference numerals that are the same as those of Embodiments 4 and 5, and description thereof will be omitted.

The voltage measuring device according to Embodiment 7 is one resulting from combination of features of the voltage measuring device according to Embodiment 4 and features of the voltage measuring device according to Embodiment 5. In Embodiment 7, a switch 25, a switch 26, a switch 27, a switch 28 and a switch 29 are provided.

One front end side of the switch 25 is connected to one rear end side of a switch 15. The other front end side of the switch 25 is connected to a front end side of a voltage measuring circuit 8. A rear end side of the switch 25 is connected to a front end side of a capacitor 17. A front end side of the switch 26 is connected to a rear end side of the capacitor 17. The other rear end side of the switch 26 is connected to a front end side of the voltage measuring circuit 8.

One front end side of the switch 27 is connected to the other rear end side of the switch 15. The other front end side of the switch 27 is connected to a front end side of the voltage measuring circuit 8. A rear end side of the switch 27 is connected to a front end side of a capacitor 19. A front end side of the switch 28 is connected to a rear end side of the capacitor 19. The other rear end side of the switch 28 is connected to a front end side of the voltage measuring circuit 8.

One front end side of the switch 29 is connected to one rear end side of the switch 26. The other front end side of the switch 29 is connected to one rear end side of the switch 28. A rear end side of the switch 29 is connected to a front end side of an electrode 23.

In the voltage measuring device, the switch 15 is shifted to the switch 25 side. Simultaneously with this, the switch 25 is shifted to the switch 15 side. Simultaneously with this, the switch 26 is shifted to the switch 29 side. Simultaneously with this, the switch 29 is shifted to the switch 26 side.

Here, the capacitor 17 has a potential Va provided by a potential Vp and a potential Vg. Subsequently, the switch 25 and the switch 26 are shifted to the voltage measuring circuit 8 side. Here, the voltage measuring circuit 8 calculates (Vp−Vg)/(Ca/C1+1+Ca/C2) as the potential Va.

In the voltage measuring device, the switch 15 is shifted to the switch 27. Simultaneously with this, the switch 27 is shifted to the switch 15 side. Simultaneously with this, the switch 28 is shifted to the switch 29 side. Simultaneously with this, the switch 29 is shifted to the switch 28 side.

Here, the capacitor 19 has a potential Vb provided by the potential Vp and the potential Vg. Subsequently, the switches 27 and 28 are shifted to the voltage measuring circuit 8 side. Here, the voltage measuring circuit 8 calculates (Vp−Vg)/(Cb/C1+1+Cb/C2) as the potential Vb.

Subsequently, the voltage measuring circuit 8 eliminates an electrostatic capacitance C1 and an electrostatic capacitance C2 from the potential Va and the potential Vc. More specifically, the voltage measuring circuit 8 calculates Va/(Ca((1/Vb−1/Va)/(Ca/Va−Cb/Vb))+1) as a potential difference (Vp−Vg) in a measurement target.

According to Embodiment 7 described above, while the signal common-side potential Vp is contactlessly measured, as in Embodiment 3, an error in measurement of the potential difference (Vp−Vg) in a measurement target can be made small even if there is change in measurement conditions.

Also, the voltage measuring circuit 8 may be configured so as to be similar to that of Embodiment 1 to alternately measure the potential Va and the potential Vb by flips of a switch (not illustrated). Also, two voltage measuring circuits 8 may be provided for the respective capacitors 17 and 19.

### INDUSTRIAL APPLICABILITY

As described above, a voltage measuring device according to the present invention can be used when contactlessly measuring a direct-current voltage of a measurement target.

### DESCRIPTION OF SYMBOLS

1 conductor, 2 dielectric body, 3 electrode, 4 capacitor, 5 switch, 6 switch, 7 signal common, 8 voltage measuring circuit, 8a differential amplifier, 8b switch, 8c hold capacitor, 8d buffer amplifier, 9 capacitor, 10 measurement target, 11 capacitor, 12 line resistance, 13 voltage measuring circuit, 14 common, 15 switch, 16 switch, 17 capacitor, 18 switch, 19 capacitor, 20 switch, 21 conductor, 22 dielectric body, 23 electrode, 24 capacitor, 25 switch, 26 switch, 27 switch, 28 switch, 29 switch

1-8. (canceled)

9: A voltage measuring device comprising:
a dielectric body provided so as to be able to face a conductor of a measurement target;
an electrode provided on the dielectric body;
a first capacitor that upon being connected to the electrode, holds a potential that has a one-to-one correlation with a potential of the electrode;
a second capacitor that upon being connected to the electrode, holds a potential having a one-to-one correlation with the potential of the electrode;
a first switch including a front end side and a pair of rear end sides, the front end side being connected to the electrode;
a second switch including a pair of front end sides and a rear end side, one of the front end sides being connected to one of the rear end sides of the first switch, the rear end side being connected to the first capacitor;
a third switch including a pair of front end sides and a rear end side, one of the front end sides being connected to the other of the rear end sides of the first switch, the rear end side being connected to the second capacitor; and
a fourth switch including a pair of front end sides and a rear end side, one of the front end sides being connected to the other of the front end sides of the second switch, the other of the front end sides being connected to the other of the front end sides of the third switch.

10: The voltage measuring device according to claim 9, comprising a voltage measuring circuit to which the rear end side of the fourth switch is connected.

11: The voltage measuring device according to claim 9,
wherein the electric body includes two dielectric bodies provided so as to face two conductors of the measurement target, respectively;
wherein the electrode includes two electrodes provided on the two dielectric bodies, respectively; and
wherein the first switch, the second switch, the third switch and the fourth switch are provided for each of the two electrodes.

12: The voltage measuring device according to claim 11, wherein the first capacitor and the second capacitor each have a capacitance that is smaller than a capacitance determined by one of the two conductors, one of the dielectric bodies and one of the electrodes and a capacitance determined by the other of the two conductors, the other of the dielectric bodies and the other of the electrodes so that a difference between a potential difference between the two conductors and a voltage between opposite ends of the capacitor is smaller than a preset value.
